(19) United States
(12) Patent Application Publication
(10) Pub. No.: US 2024/0413004 A1
(43) Pub. Date: Dec. 12, 2024

(54) SEMICONDUCTOR DEVICE MANUFACTURING METHOD FOR REDUCING RANDOM DOPANT FLUCTUATION

(71) Applicant: NANYA TECHNOLOGY CORPORATION

(72) Inventors: Yu Jie JIANG, New Taipei City (TW); Tseng-Fu LU, Taoyuan City (TW); Jhen-Yu TSAI, Kaohsiung City (TW)

(21) Appl. No.: 18/207,591

(22) Filed: Jun. 8, 2023

(51) Int. Cl. H01L 21/762; H01L 21/324; H01L 21/8238; H01L 29/08

(52) U.S. Cl. CPC H01L 21/76224; H01L 21/324; H01L 21/823814; H01L 29/0847

(57) ABSTRACT

A semiconductor device manufacturing method includes the following steps. A well implant process is performed on a region of a substrate. A source/drain implant process is performed on the region of the substrate. An active area is defined on the region of the substrate. Shallow trench isolations are formed in the active area. An annealing process is performed to the region of the substrate.

### BACKGROUND

### Field of Disclosure

The present disclosure relates to a semiconductor device and manufacturing method thereof.

### Description of Related Art

An integrated circuit (IC) device (also referred to as a semiconductor chip) can contain millions of transistors and other circuit elements that are fabricated on a single silicon crystal substrate (wafer). In recent years, the size of an IC device was rapidly scaled down for cost reduction and high volume manufacturing. Several problems were occurred in nano-scaled devices, such as random dopant fluctuation.

### SUMMARY

The present disclosure provides semiconductor device manufacturing methods to deal with the needs of the prior art problems.

In one or more embodiments, a semiconductor device manufacturing method includes: performing a well implant process on a region of a substrate; performing a source/drain implant process on the region of the substrate; defining an active area on the region of the substrate; forming shallow trench isolations (STI) in the active area; and performing an annealing process to the region of the substrate.

In one or more embodiments, the source/drain implant process is performed after performing the well implant process.

In one or more embodiments, the active area is defined after performing the source/drain implant process.

In one or more embodiments, the annealing process is performed after forming the STI.

In one or more embodiments, the annealing process includes a first annealing step using a first annealing temperature and a second annealing step using a second annealing temperature, the first annealing temperature is lower than the second annealing temperature.

In one or more embodiments, the first annealing step is a shallow-trench-isolation annealing.

In one or more embodiments, the second annealing step is a dopant-activation annealing.

In one or more embodiments, the dopant-activation annealing is performed by a rapid thermal annealing system.

In one or more embodiments, forming the STI includes etching the region to form trenches and forming insulation materials in the trenches.

In one or more embodiments, the insulation materials comprise oxide and nitride materials.

In one or more embodiments, a semiconductor device manufacturing method includes: performing a dopant implant process on a region of a substrate; forming an active area and shallow trench isolations on the region of the substrate after performing the dopant implant process; and performing an annealing process to the region of the substrate.

In one or more embodiments, performing the dopant implant process includes performing a well implant process and performing a source/drain implant process.

In one or more embodiments, the annealing process is performed after forming the shallow trench isolations.

In one or more embodiments, the annealing process includes a first annealing step using a first annealing temperature and a second annealing step using a second annealing temperature, the first annealing temperature is lower than the second annealing temperature.

In one or more embodiments, the first annealing step is a shallow-trench-isolation annealing.

In one or more embodiments, the second annealing step is a dopant-activation annealing.

In sum, the semiconductor device manufacturing method disclosed herein performs a dopant implant process on a broad region of a substrate before active regions being defined or shallow trench isolations being formed, thereby facilitating a reduction in random dopant fluctuation.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates an active area portion of a semiconductor substrate according to some embodiments of the present disclosure;

FIG. 2 illustrates a semiconductor substrate with device regions and STI regions according to some embodiments of the present disclosure;

FIG. 3 illustrates a cross-sectional view of a first transistor device in an early stage according to some embodiments of the present disclosure;

FIG. 4 illustrates a cross-sectional view of a second transistor device in an early stage according to some embodiments of the present disclosure;

FIG. 5 illustrates another cross-sectional view of a first transistor device according to some embodiments of the present disclosure;

FIG. 6 illustrates another cross-sectional view of a second transistor device according to some embodiments of the present disclosure;

FIG. 7 illustrates a diagram showing a voltage change between the first transistor device and the second transistor device;

FIG. 8 illustrates a diagram showing a current change between the first transistor device and the second transistor device;

FIG. 9 illustrates a diagram showing another current change between the first transistor device and the second transistor device;

FIG. 10 illustrates partial manufacturing steps of the first transistor device according to some embodiments of the present disclosure; and

FIG. 11 illustrates partial manufacturing steps of the second transistor device according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

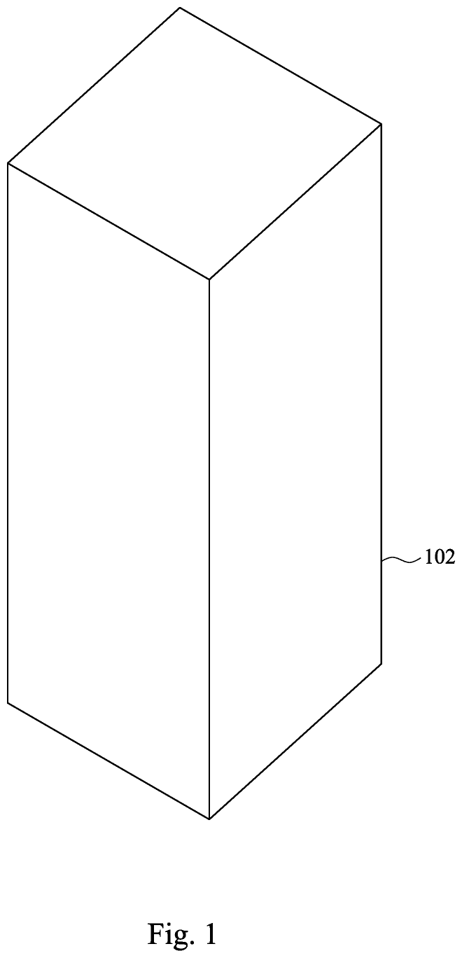

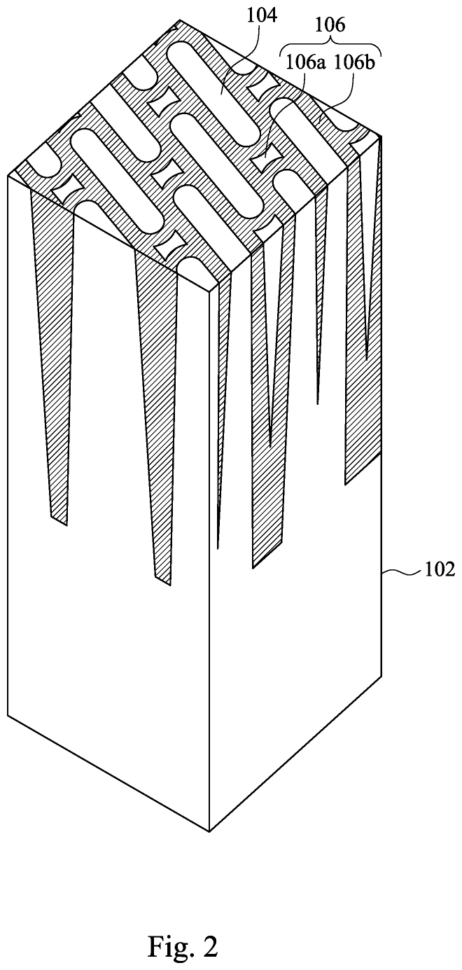

Reference is made to FIGS. 1 and 2, FIG. 1 illustrates an active area portion of a semiconductor substrate according to some embodiments of the present disclosure, and FIG. 2 illustrates a semiconductor substrate with device regions and STI regions according to some embodiments of the present disclosure. The term “active area” refers to the region of a semiconductor device where electrical current flows and the primary functionality of the device occurs. It is the portion of the semiconductor material that is intentionally doped or modified to create the desired electronic behavior. An active area 102 is defined in a semiconductor substrate, and shallow trench isolations 106 are formed between adjacent device regions 104 on a substrate. The term “Shallow Trench Isolation (STI)” is also referred to a technique used in semiconductor manufacturing to electrically isolate adjacent active regions or devices on a silicon substrate. It helps prevent unwanted electrical interactions and leakage currents between different components, ensuring the proper functioning and reliability of the integrated circuits (ICs).

The process of manufacturing the shallow trench isolations 106 typically involves the following steps.

Substrate preparation: a semiconductor wafer, usually made of silicon, is cleaned and prepared for further processing.

Trench formation: a pattern is created on the wafer surface using lithography techniques. The pattern defines the location and dimensions of the isolation trenches. A masking material, such as photoresist, is applied and exposed to ultraviolet (UV) light through a mask, followed by development to form a photoresist pattern.

Etching: the exposed silicon dioxide (SiO₂) areas are etched away using a dry or wet etching process, forming the shallow trenches. The depth of the trenches is typically in the range of a few hundred nanometers to a few micrometers.

Liner deposition: A thin layer of oxide, called a liner, is deposited on the sidewalls and the bottom of the trenches. The liner material is usually silicon dioxide (SiO₂) or another suitable dielectric material. The liner helps improve the electrical isolation and prevents contaminants from diffusing into the active areas.

Trench fill: The trenches are filled with a dielectric material, such as chemical vapor deposition (CVD) oxide or a combination of oxide (e.g., oxide 106b) and other materials like silicon nitride (e.g., nitride 106a). The excess fill material is typically removed using a chemical mechanical planarization (CMP) process, which levels the wafer surface.

Planarization: The wafer surface is planarized to ensure a uniform and flat surface across the wafer, eliminating any irregularities or topographic variations caused by the trench filling process.

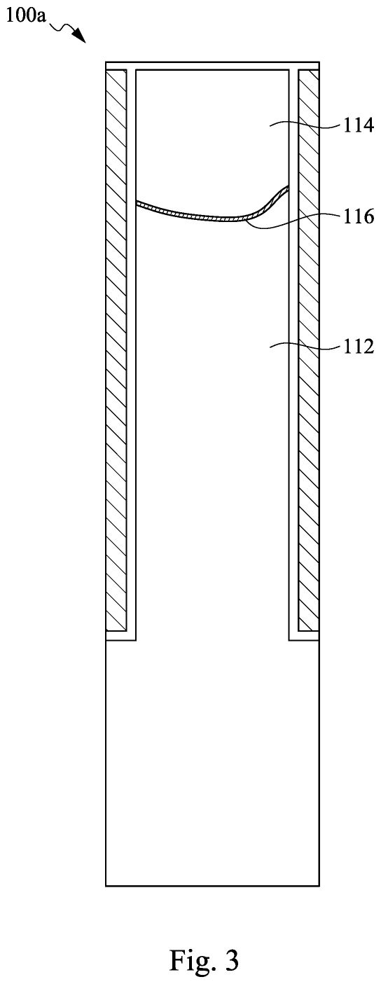

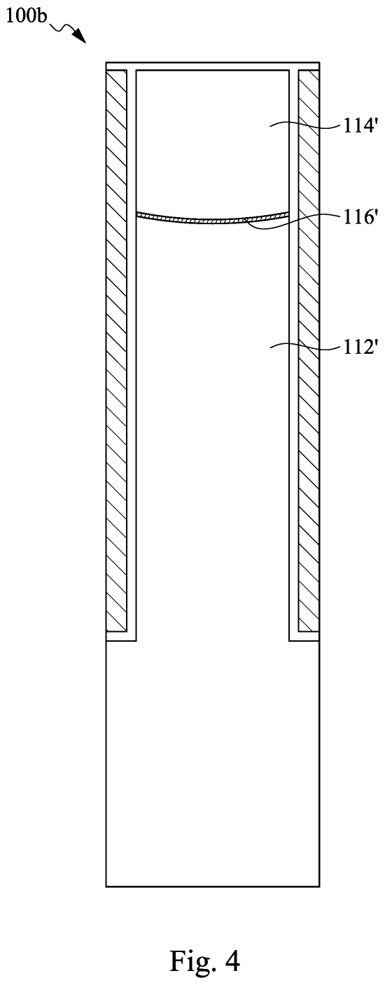

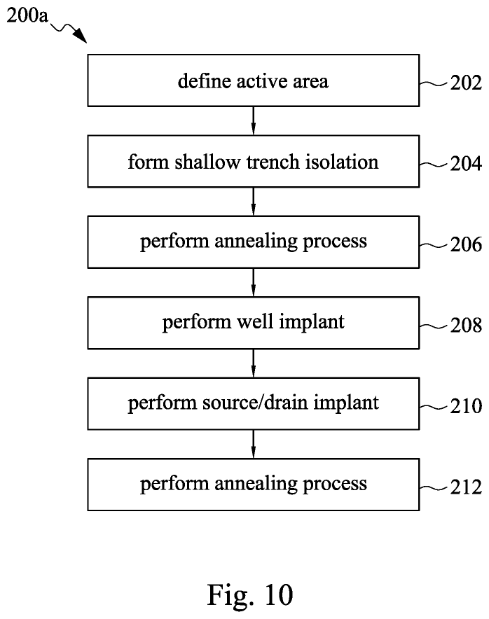

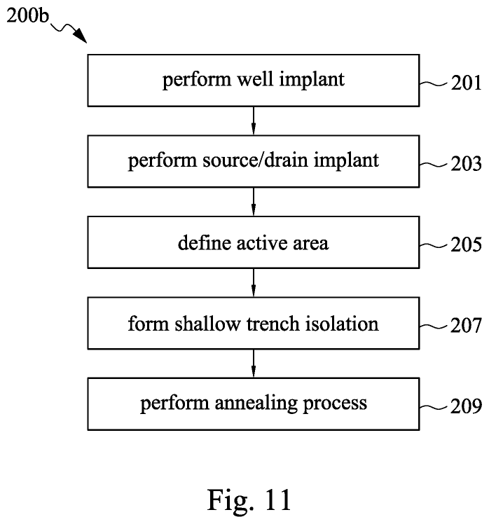

Reference is made to FIGS. 3 and 4, FIG. 3 illustrates a cross-sectional view of a first transistor device 100a in an early stage according to some embodiments of the present disclosure, and FIG. 4 illustrates a cross-sectional view of a second transistor device 100b in an early stage according to some embodiments of the present disclosure. In some embodiments of the present disclosure, the first transistor device 100a is typically manufactured by a first manufacturing method, e.g., a manufacturing method 200a in FIG. 10 while the second transistor device 100b is typically manufactured by a second manufacturing method, e.g., a manufacturing method 200b in FIG. 11. The second transistor device 100b is manufactured by the manufacturing method 200b with a better distribution of dopant atoms within the semiconductor material than the first transistor device 100a manufactured by the manufacturing method 200a. That is, the manufacturing method 200b is proposed to manufacture a semiconductor device to reduce a random dopant fluctuation (RDF). RDF becomes particularly significant as transistors shrink in size and approach nanoscale dimensions. As the dimensions of transistors decrease, the number of dopant atoms within the active region of the device also decreases. Consequently, the impact of individual dopant atoms becomes more pronounced, leading to increased variability in device characteristics. The first transistor device 100a has a well-implanted region 112, a source/drain region 114 and a junction 116 therebetween. The second transistor device 100b has a well-implanted region 112′, a source/drain region 114′ and a junction 116′ therebetween.

Reference is made to FIGS. 10 and 11, FIG. 10 illustrates partial manufacturing steps of the first transistor device according to some embodiments of the present disclosure, and FIG. 11 illustrates partial manufacturing steps of the second transistor device according to some embodiments of the present disclosure. The manufacturing method 200a includes steps 202, 204, 206, 208, 210 and 212. In step 202 of the manufacturing method 200a, a region or a portion of a substrate is defined as “active area”, e.g., the active area 102 in the semiconductor substrate of FIG. 1.

In step 204 of the manufacturing method 200a, shallow trench isolations, e.g., shallow trench isolations 106 in the semiconductor substrate of FIG. 2, are formed between adjacent device regions 104 to electrically isolate adjacent active regions or devices.

In step 206 of the manufacturing method 200a, an annealing process is performed to the shallow trench isolations 106 between adjacent device regions 104. The annealing process after forming Shallow Trench Isolation (STI) plays a crucial role in relieving stress, enhancing the properties of the insulating material, achieving a planar surface, and improving electrical isolation. Regarding stress relief, the STI process involves etching trenches into the silicon substrate and filling them with an insulating material, typically an oxide. This process can introduce mechanical stress in the surrounding silicon regions due to the differences in thermal expansion coefficients between the silicon and the insulator. Annealing helps relieve this stress by allowing the silicon lattice to relax and adjust its structure, reducing the potential for strain-induced defects. Regarding enhancing the properties of the insulating material, the filling material used in the STI process, such as silicon dioxide (SiO₂), may not have a perfectly dense structure immediately after deposition. Annealing the wafer at high temperatures helps promote the densification of the oxide material, improving its electrical and mechanical properties. Densification reduces the occurrence of defects, such as voids or weak interfaces, and enhances the insulating performance of the STI structure. Regarding planarization, the STI formation process often leaves the oxide material protruding above the silicon surface, resulting in a non-planar topography. Annealing can facilitate the planarization of the STI structure by causing the oxide material to flow and smoothen out the surface. This planarization step is crucial for subsequent processing steps, such as depositing metal or dielectric layers, to ensure uniformity and proper adhesion. Regarding electrical isolation enhancement, the primary purpose of STI is to provide electrical isolation between adjacent active regions in a semiconductor device, such as transistors. Annealing can improve the quality of the oxide-Si interface, reducing leakage currents and enhancing the isolation characteristics. The annealing process helps remove any contaminants or impurities that might have been introduced during the STI formation, leading to improved electrical performance and device reliability.

In step 208 of the manufacturing method 200a, a well implant process is performed to the device regions, e.g., the device regions 104 in FIG. 1, with the shallow trench isolations 106 shielded or masked. The well implant process is configured to form the well-implanted region 112 of the first transistor device 100a. A p-type dopant, e.g., Boron, is used to create p-wells in CMOS technology. It introduces acceptor states in the semiconductor lattice, resulting in an excess of holes, which leads to a p-type behavior. An n-type dopant, e.g., Phosphorus, Arsenic or Antimony, is used to create n-wells in CMOS technology. It introduces donor states in the semiconductor lattice, resulting in an excess of electrons, which leads to an n-type behavior. The selection of dopants for well implantation is based on the desired doping concentration, electrical characteristics, and the overall device requirements. The dopant species and concentration determine the conductivity and threshold voltage of the resulting well regions, which are crucial parameters in controlling the behavior of transistors and other semiconductor devices.

In step 210 of the manufacturing method 200a, a source/drain implant process is performed to the device regions, e.g., the device regions 104 in FIG. 2, with the shallow trench isolations 106 shielded or masked. The “source/drain implant process” refers to the step in which dopant atoms are intentionally implanted into the source and drain regions of a transistor. The source/drain implant process is configured to form the source/drain region 114 of the first transistor device 100a. A p-type dopant, e.g., Boron, is used for implanting into the source and drain regions of p-channel transistors. It introduces acceptor states in the semiconductor lattice, creating p-type regions that facilitate the formation of p-n junctions, e.g., the junction 116 in FIG. 3. An n-type dopant, e.g., Phosphorus, Arsenic or Antimony, is used for implanting into the source and drain regions of n-channel transistors. It introduces donor states in the semiconductor lattice, creating n-type regions that promote the formation of n-p junctions, e.g., the junction 116 in FIG. 3.

In step 212 of the manufacturing method 200a, another annealing process is performed to the first transistor device 100a. This annealing process is equipped with different purposes from the annealing process in step 206, and configured to activate and redistribute dopants within the crystal lattice of the semiconductor material. The implantation of dopants involves the introduction of impurity atoms into the semiconductor substrate to modify its electrical properties. During the implantation process, high-energy ions are accelerated and directed towards the surface of the semiconductor material. These ions penetrate the material and become embedded within the crystal lattice, disrupting its regular arrangement. This implantation process introduces electrically active dopant atoms into specific regions of the semiconductor, creating regions with altered conductivity characteristics. However, the dopants implanted through ion implantation are usually in an electrically inactive state and may not contribute significantly to the desired electrical behavior of the semiconductor device. Therefore, an annealing process is performed to activate the dopants and restore the crystal lattice structure.

The manufacturing method 200b includes steps 201, 203, 205, 207 and 209. In step 201 of the manufacturing method 200b, a well implant process is performed to substrate in FIG. 1 without active regions being defined or shallow trench isolations being formed. This well implant process is configured to form the well-implanted region 112′ of the second transistor device 100b. P-type dopants or n-type dopants may be used similar to the step 208 of the manufacturing method 200a to achieve the same purposes. Since step 201 is performed on a broad region of a semiconductor substrate without active regions being defined or shallow trench isolations being formed, the dopants can be implanted in wells with a better distribution of dopant atoms within the semiconductor material.

In step 203 of the manufacturing method 200b, a source/drain implant process is performed to the substrate in FIG. 1 without active regions being defined or shallow trench isolations being formed. This source/drain implant process is configured to form the source/drain region 114′ of the second transistor device 100b. P-type dopants or n-type dopants may be used similar to the step 210 of the manufacturing method 200a to achieve the same purposes. Since step 203 is performed on a broad region of a semiconductor substrate without active regions being defined or shallow trench isolations being formed, the dopants can be implanted in wells with a better distribution of dopant atoms within the semiconductor material.

In step 205 of the manufacturing method 200b, a region or a portion of a substrate is defined as “active area”, e.g., the active area 102 in the semiconductor substrate of FIG. 1. This step 205 is similar to step 202 of the manufacturing method 200a, but is performed after the well implant process and the source/drain implant process.

In step 207 of the manufacturing method 200b, shallow trench isolations, e.g., shallow trench isolations 106 in the semiconductor substrate of FIG. 2, are formed between adjacent device regions 104 to electrically isolate adjacent active regions or devices. This step 207 is similar to step 204 of the manufacturing method 200a, but is performed after the well implant process and the source/drain implant process. In step 207, the shallow trenches may be etched with higher power (i.e., in dry etch) or longer etching time than step 204 because the substrate is implanted with dopants.

In step 209 of the manufacturing method 200b, an annealing process is performed to the second transistor device 100b. The annealing process may include a shallow-trench-isolation annealing as a first annealing step using a first annealing temperature and a dopant-activation annealing as a second annealing step using a second annealing temperature, wherein the first annealing temperature is lower than the second annealing temperature. The shallow-trench-isolation (STI) annealing is performed to relieve stress, improve the quality of the isolation oxide, and ensure the integrity of the surrounding transistor structures. The purpose of STI annealing process is primarily to optimize the properties of the isolation oxide material rather than activate dopants. The STI anneal is typically conducted at a lower temperature compared to the dopant-activation annealing, typically in the range of a few hundred degrees Celsius. The equipment used for STI annealing can include furnace systems, rapid thermal processing tools, or specialized annealing chambers tailored for oxide annealing. The dopant-activation annealing is performed directly and continuously after the STI anneal, and configured to activate the dopants and restore the crystal lattice structure, as mentioned in step 212. The temperature required for this annealing process is typically high, ranging from several hundred to over a thousand degrees Celsius, depending on the specific dopants and the target device requirements. This high-temperature annealing is often performed using specialized equipment such as rapid thermal annealing (RTA) systems or furnace annealing chambers. Compared to the manufacturing method 200a, the annealing process in step 209 includes the shallow-trench-isolation annealing and the dopant-activation annealing that are performed continuously right after forming shallow trench isolations. Although the shallow-trench-isolation annealing is performed at lower temperature than the dopant-activation annealing, it still has thermal effect causing dopant-activation.

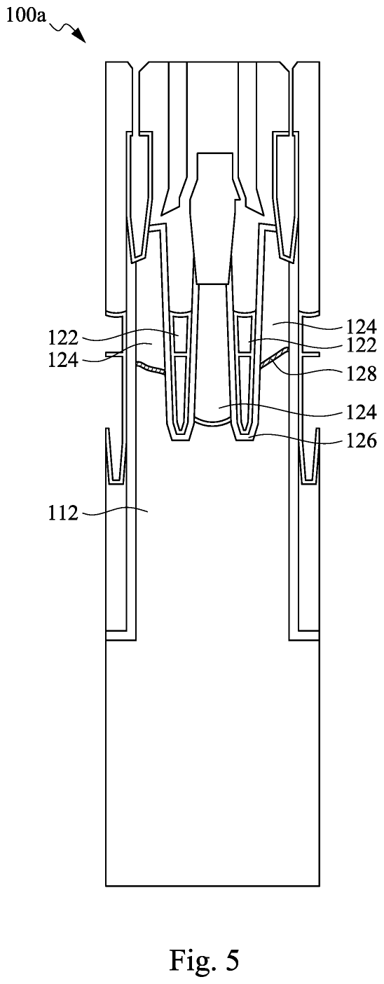

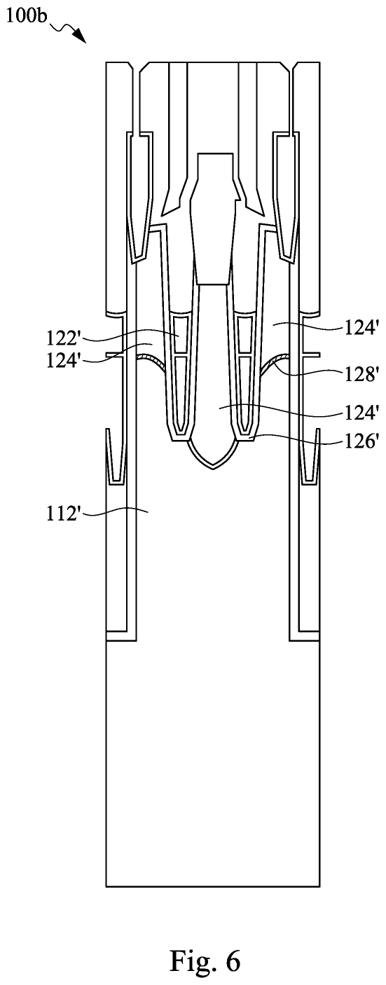

Reference is made to FIGS. 5 and 6, FIG. 5 illustrates another cross-sectional view of a first transistor device according to some embodiments of the present disclosure, and FIG. 6 illustrates another cross-sectional view of a second transistor device according to some embodiments of the present disclosure. The first transistor device 100a is manufactured based upon the manufacturing method 200a. There are two junctions 126 and 128 in the first transistor device 100a of FIG. 5. The junction 126 is present between a bit line contact 122 and a well-implanted region 112 underneath. The junction 128 is present between a cell contact 124 and the well-implanted region 112 underneath. The second transistor device 100b is manufactured based upon the manufacturing method 200b. There are also two junctions 126′ and 128′ in the second transistor device 100b of FIG. 6. The junction 126′ is present between a bit line contact 122′ and a well-implanted region 112′ underneath. The junction 128′ is present between a cell contact 124′ and the well-implanted region 112′ underneath. The junction 126′ is aligned to the junction 126 with about the same depth while the junction 128′ is aligned to the junction 128 with about the same depth. And the junction 116′ is aligned with the junction 116 with about the same depth in FIGS. 3 and 4. In order to achieve aligned junctions (116, 116′), aligned junctions (126, 126′) and aligned junctions (128,128′), steps 201 and 203 of the manufacturing method 200b should be performed with smaller power and lower density of dopants relative to steps 208 and 210 of the manufacturing method 200a to relieve the thermal effect of continuously performing the shallow-trench-isolation annealing and the dopant-activation annealing.

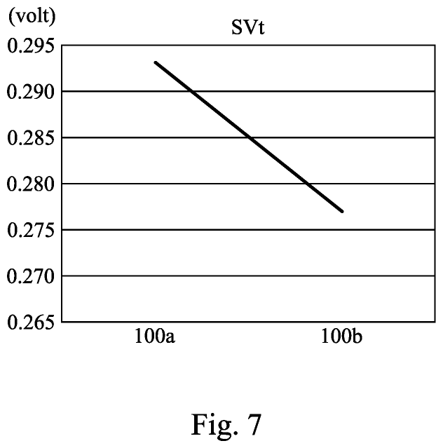

Reference is made to FIG. 7, which illustrates a diagram showing a voltage change between the first transistor device and the second transistor device. An operating voltage SVt of the second transistor device 100b is about 5.5% lower than an operating voltage SVt of the first transistor device 100a due to the tuned junction profile.

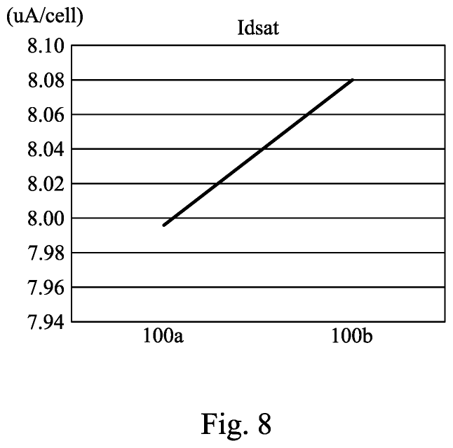

Reference is made to FIG. 8, which illustrates a diagram showing a current change between the first transistor device and the second transistor device. A saturation current Idsat of the second transistor device 100b is about 1.1% greater than a saturation current Idsat of the first transistor device 100a due to the tuned junction profile.

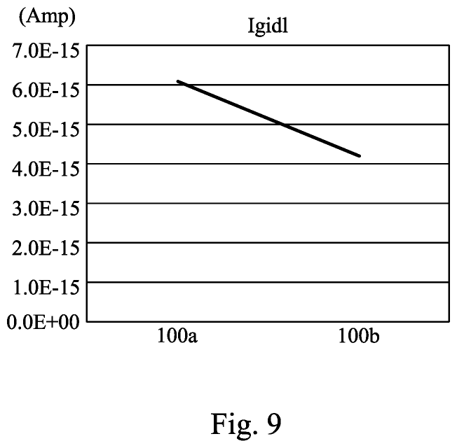

Reference is made to FIG. 9, which illustrates a diagram showing another current change between the first transistor device and the second transistor device. An idle current Igidl of the second transistor device 100b is about 30.4% lower than an idle current Igidl of the first transistor device 100a due to the tuned junction profile.

In sum, the semiconductor device manufacturing method disclosed herein performs a dopant implant process on a broad region of a substrate before active regions being defined or shallow trench isolations being formed, thereby facilitating a reduction in random dopant fluctuation.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device manufacturing method comprising:
performing a well implant process on a region of a substrate;
performing a source/drain implant process on the region of the substrate;
defining an active area on the region of the substrate;
forming shallow trench isolations (STI) in the active area; and
performing an annealing process to the region of the substrate.

2. The method of claim 1, wherein the source/drain implant process is performed after performing the well implant process.

3. The method of claim 1, wherein the active area is defined after performing the source/drain implant process.

4. The method of claim 1, wherein the annealing process is performed after forming the STI.

5. The method of claim 1, wherein the annealing process comprises a first annealing step using a first annealing temperature and a second annealing step using a second annealing temperature, the first annealing temperature is lower than the second annealing temperature.

6. The method of claim 5, wherein the first annealing step is a shallow-trench-isolation annealing.

7. The method of claim 5, wherein the second annealing step is a dopant-activation annealing.

8. The method of claim 7, wherein the dopant-activation annealing is performed by a rapid thermal annealing system.

9. The method of claim 1, wherein forming the STI comprises etching the region to form trenches and forming insulation materials in the trenches.

10. The method of claim 9, wherein the insulation materials comprise oxide and nitride materials.

11. A semiconductor device manufacturing method comprising:
performing a dopant implant process on a region of a substrate;
forming an active area and shallow trench isolations on the region of the substrate after performing the dopant implant process; and
performing an annealing process to the region of the substrate.

12. The method of claim 11, wherein performing the dopant implant process comprises performing a well implant process and performing a source/drain implant process.

13. The method of claim 11, wherein the annealing process is performed after forming the shallow trench isolations.

14. The method of claim 11, wherein the annealing process comprises a first annealing step using a first annealing temperature and a second annealing step using a second annealing temperature, the first annealing temperature is lower than the second annealing temperature.

15. The method of claim 14, wherein the first annealing step is a shallow-trench-isolation annealing.

16. The method of claim 14, wherein the second annealing step is a dopant-activation annealing.
